(19) United States
(12) Patent Application Publication
(10) Pub. No.: US 2010/0101651 A1
(43) Pub. Date: Apr. 29, 2010

(54) POLYMER SOLAR CELLS

(75) Inventors: Ching-Yen WEI, Taipei City (TW); Feng-Yu YANG, Zhubei City (TW); Meei-Yu HSU, Kaohsiung (TW); Gue-Wuu HWANG, Hsinchu City (TW); Yi-Ling CHEN, Zhubei City (TW)

Correspondence Address: LOWE HAUPTMAN HAM & BERNER, LLP, 1700 DIAGONAL ROAD, SUITE 300, ALEXANDRIA, VA, 22314, US

(73) Assignee: INDUSTRIAL TECHNOLOGY RESEARCH INSTITUTE, Hsinchu (TW)

(21) Appl. No.: 12/330,139

(22) Filed: Dec. 8, 2008

(30) Foreign Application Priority Data
Oct. 29, 2008 (TW) 97141558

(51) Int. Cl. H01L 31/00

(52) U.S. Cl. 136/263

(57) ABSTRACT

A polymer solar cell is provided. The polymer solar cell includes a cathode and an anode, an active layer having a first surface and a second surface disposed between the cathode and the anode, and a titanium dioxide layer formed on one of the first and second surfaces of the active layer.

### CROSS REFERENCE TO RELATED APPLICATIONS

This Application claims priority of Taiwan Patent Application No. 97141558, filed on Oct. 29, 2008, the entirety of which is incorporated by reference herein.

### BACKGROUND OF THE INVENTION

1. Field of the Invention

The invention relates to a polymer solar cell, and more particularly to a polymer solar cell coated with a titanium dioxide layer.

2. Description of the Related Art

Compared to chip-type solar cells and thin-film solar cells, a polymer solar cell possesses higher efficiency at a lower cost. With reliability and efficiency thereof further improved, the application of polymer solar cell is expected to increase.

An active layer of a polymer solar cell comprises a p-n material such as poly(3-hexylthiophene) (P3HT)/(6,6)-phenyl C61-butyric acid methyl ester (PCBM). Such active layer materials possess low cost, light weight, flexibility and a potential for application in large-area device fabrication.

However, such active layer polymer materials are easily damaged by sunlight (ultraviolet, 250-400 nm), deteriorating cell efficiency and reducing lifespan. Thus, development of a polymer solar cell capable of protecting the active layer polymer materials from ultraviolet damage is desirable.

### BRIEF SUMMARY OF THE INVENTION

One embodiment of the invention provides a polymer solar cell comprising a cathode and an anode, an active layer having a first surface and a second surface disposed between the cathode and the anode and a titanium dioxide layer formed on one of the first surface and the second surface of the active layer.

A modified titanium dioxide nano crystal is coated on an active layer of a polymer solar cell through a solution process to protect the active layer, effectively improving cell stability and lifespan.

A detailed description is given in the following embodiments with reference to the accompanying drawings.

### BRIEF DESCRIPTION OF THE DRAWINGS

The invention can be more fully understood by reading the subsequent detailed description and examples with references made to the accompanying drawing, wherein:

FIG. 1 is a cross-sectional view of a polymer solar cell according to an embodiment of the invention.

FIG. 2 shows a comparison of cell efficiency between a polymer solar cell provided by the invention and a conventional polymer solar cell.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

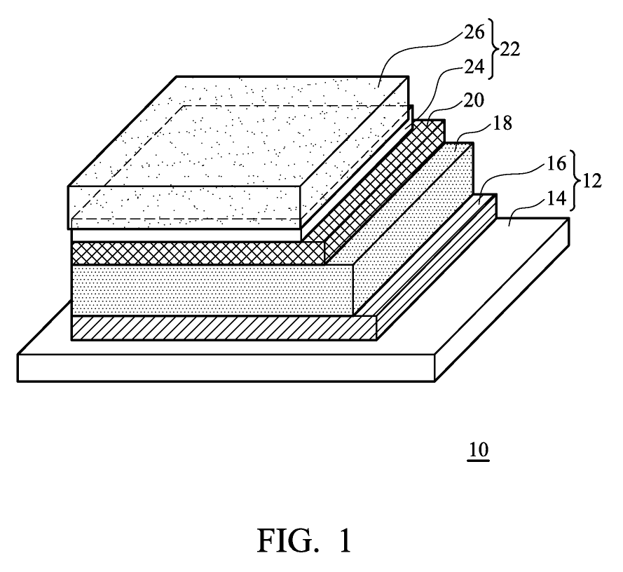

Referring to FIG. 1, a polymer solar cell in an embodiment of the invention is disclosed. A polymer solar cell 10 comprises a composite anode 12, an active layer 18, a titanium dioxide layer 20 and a composite cathode 22. The active layer 18 is disposed between the composite anode 12 and the composite cathode 22. The titanium dioxide layer 20 is formed on the active layer 18.

The composite anode 12 comprises an anode 14 and a material layer 16 coated thereon. The anode 14 may be an ITO glass. The material layer 16 may comprise conductive polymers such as poly(3,4-ethylenedioxythiophene) (PEDOT) or poly(styrene sulfonate) (PSS).

The active layer 18 may comprise polymer semiconductors such as poly(3-hexylthiophene) (P3HT) or poly[2-methoxy-5-(3,7-dimethyloctyloxy)-1,4-phenylenevinylene] (MDMO-PPV) and fullerene derivatives such as (6,6)-phenyl C61-butyric acid methyl ester (PCBM).

The titanium dioxide layer 20 may comprise titanium dioxide-containing nano structures. The titanium dioxide-containing nano structure may comprise a titanium dioxide crystal and a compound formed on the surface thereof. The titanium dioxide crystal may be an anatase titanium dioxide crystal, with a size of 18-22 nm×2-6 nm. The compound may comprise carboxyl-containing compounds or phosphonate-containing compounds. The carboxyl-containing compound may comprise C18 acidic compounds such as oleic acid. The phosphonate-containing compound may comprise surfactants such as diethyl(2-cyanoethyl)phosphonate, diethyl(2-oxopropyl)phosphonate, triethyl-3-phosphonopropionate or diethyl(2-oxo-2-phenylethyl)phosphonate or polymer compounds having the formula

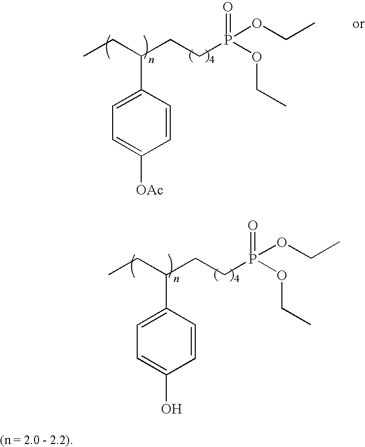

The composite cathode 22 comprises a material layer 24 and a cathode 26 formed thereon. The material layer 24 may comprise LiF. The cathode 26 may comprise aluminum.

A modified titanium dioxide nano crystal is coated on an active layer of a polymer solar cell through a solution process to protect the active layer, effectively improving cell stability and lifespan.

### EXAMPLE 1

Preparation of a Titanium Dioxide-Containing Nano Structure (1)

(1) Synthesis of titanium dioxide-oleic acid

78 ml oleic acid was added to a 250 ml reaction bottle. Nitrogen gas was then conducted thereinto through a needle. Next, the reaction bottle was heated to 120° C. to remove water. After reaction for 1 hour, the temperature was cooled to 100° C. and the needle was removed. 2.95 ml titanium (IV) isopropoxide (TTIP) was then added. Next, a trimethylamine-N-oxide (TMAO) aqueous solution (2.22 g TMAO was dissolved in 10ml water) was added to react for 6 hours. After cooling to room temperature, 200 ml methanol was added and a centrifugation was processed. After washing with methanol for several times and drying, 1.2 g titanium dioxide-oleic acid was obtained.

(2) Synthesis of titanium dioxide-oleic acid/diethyl(2-cyanoethyl)phosphonate

0.2 g titanium dioxide-oleic acid, 0.1 g diethyl(2-cyanoethyl)phosphonate and 2 ml chlorobenzene were added to a 50 ml reaction bottle. After the titanium dioxide was completely dissolved in solvent through ultrasonic vibration, the reaction bottle was heated under 100° C. for 24 hours. After removal of solvent, a titanium dioxide-containing nano structure of titanium dioxide-oleic acid/diethyl(2-cyanoethyl) phosphonate was prepared.

### EXAMPLE 2

Preparation of a Titanium Dioxide-Containing Nano Structure (2)

(1) Synthesis of titanium dioxide-oleic acid

78 ml oleic acid was added to a 250 ml reaction bottle. Nitrogen gas was then conducted thereinto through a needle. Next, the reaction bottle was heated to 120° C. to remove water. After reaction for 1 hour, the temperature was cooled to 100° C. and the needle was removed. 2.95 ml titanium (IV) isopropoxide (TTIP) was then added. Next, a trimethylamine-N-oxide (TMAO) aqueous solution (2.22 g TMAO was dissolved in 10 ml water) was added to react for 6 hours. After cooling to room temperature, 200 ml methanol was added and a centrifugation was processed. After washing with methanol for several times and drying, 1.2 g titanium dioxide-oleic acid was obtained.

(2) Synthesis of titanium dioxide-oleic acid/P4K

0.2 g titanium dioxide-oleic acid, 0.1 g

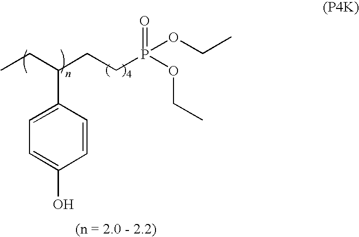

and 2 ml THF were added to a 50 ml reaction bottle. After the titanium dioxide was completely dissolved in solvent through ultrasonic vibration, the reaction bottle was heated under 60° C. for 18 hours. After removal of solvent, a titanium dioxide-containing nano structure of titanium dioxide-oleic acid/P4K was prepared.

### EXAMPLE 3

Preparation of a Polymer Solar Cell (1)

An ITO glass was washed with water, acetone and isopropanol respectively for 15 min. After applying plasma for 5 min, a material layer (PEDOT/PSS) was coated thereon with a thickness of 30 nm. The ITO glass with the PEDOT/PSS material layer was then heated at 80° C. for 10 min to prepare a composite anode. Next, P3HT and PCMB were dissolved in chlorobenzene with a weight ratio of 1:0.6 to prepare a solution, with continuous stirring for 24 hours (in a glove box). The solution was then coated on the PEDOT/PSS material layer with a thickness of 90-120 nm. After sitting for 8 hours (overnight), an active layer was prepared. Next, a 0.1 wt % anatase titanium dioxide solution (prepared by Example 1) was coated on the active layer with a rotation rate of 5,000 rpm to prepare a titanium dioxide layer. 5 Å LiF layer and 1,000 Å aluminum layer were then evaporated on the titanium dioxide layer to prepare a composite cathode. After annealing at 158° C. for 8 min, the product was packaged by UV gel. A polymer solar cell was prepared. The efficiency thereof was tested using an AM1.5 G, 1 sun light source. The efficiency was 3.59%.

### EXAMPLE 4

Preparation of a Polymer Solar Cell (2)

An ITO glass was washed with water, acetone and isopropanol respectively for 15 min. After applying plasma for 5 min, a material layer (PEDOT/PSS) was coated thereon with a thickness of 30 nm. The ITO glass with the PEDOT/PSS material layer was then heated at 80° C. for 10 min to prepare a composite anode. Next, P3HT and PCMB were dissolved in chlorobenzene with a weight ratio of 1:0.6 to prepare a solution, with continuous stirring for 24 hours (in a glove box). The solution was then coated on the PEDOT/PSS material layer with a thickness of 90-120 nm. After sitting for 8 hours (overnight), an active layer was prepared. Next, a 0.1 wt % anatase titanium dioxide solution (prepared by Example 2) was coated on the active layer with a rotation rate of 5,000 rpm to prepare a titanium dioxide layer. 5 Å LiF layer and 1,000 Å aluminum layer were then evaporated on the titanium dioxide layer to prepare a composite cathode. After annealing at 158° C. for 8 min, the product was packaged by UV gel. A polymer solar cell was prepared. The efficiency thereof was tested using an AM1.5 G, 1 sun light source. The efficiency was 2.48%.

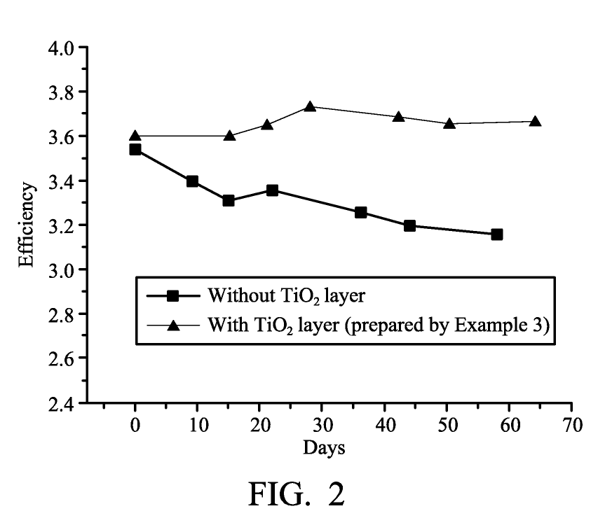

FIG. 2 shows a comparison of cell efficiency between the polymer solar cell prepared by Example 3 and a conventional polymer solar cell.

FIG. 2 indicates that the efficiency of the polymer solar cell coated with a modified titanium dioxide layer on the active layer prepared by Example 3 is apparently higher than the conventional polymer solar cell without the coated a titanium dioxide layer due to the polymer materials protecting the active layer from damage.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A polymer solar cell, comprising:
a cathode and an anode;
an active layer having a first surface and a second surface disposed between the cathode and the anode; and
a titanium dioxide layer formed on one of the first surface and the second surface of the active layer.

2. The polymer solar cell as claimed in claim 1, wherein the active layer comprises polymer semiconductors and fullerene derivatives.

3. The polymer solar cell as claimed in claim 2, wherein the polymer semiconductor comprises poly(3-hexylthiophene) (P3HT) or poly[2-methoxy-5-(3,7-dimethyloctyloxy)-1,4-phenylenevinylene] (MDMO-PPV).

4. The polymer solar cell as claimed in claim 2, wherein the fullerene derivative comprises (6,6)-phenyl C61-butyric acid methyl ester (PCBM).

5. The polymer solar cell as claimed in claim 1, wherein the titanium dioxide layer comprises titanium dioxide-containing nano structures.

6. The polymer solar cell as claimed in claim 5, wherein the titanium dioxide-containing nano structure comprises a titanium dioxide crystal and a compound formed on the surface thereof.

7. The polymer solar cell as claimed in claim 6, wherein the titanium dioxide crystal is an anatase titanium dioxide crystal.

8. The polymer solar cell as claimed in claim 7, wherein the size of the anatase titanium dioxide crystal is 18-22 nm×2-6 nm.

9. The polymer solar cell as claimed in claim 6, wherein the compound comprises carboxyl-containing compounds or phosphonate-containing compounds.

10. The polymer solar cell as claimed in claim 9, wherein the carboxyl-containing compound comprises C18 acidic compounds.

11. The polymer solar cell as claimed in claim 10, wherein the C18 acidic compound comprises oleic acid.

12. The polymer solar cell as claimed in claim 9, wherein the phosphonate-containing compound comprises diethyl(2-cyanoethyl)phosphonate, diethyl(2-oxopropyl)phosphonate, triethyl-3-phosphonopropionate or diethyl(2-oxo-2-phenylethyl)phosphonate.

13. The polymer solar cell as claimed in claim 9, wherein the phosphonate-containing compound has the formula: [chemical structure]
